(19) United States
(12) Patent Application Publication
(10) Pub. No.: US 2025/0251199 A1
(43) Pub. Date: Aug. 7, 2025

(54) VAPOR CHAMBER

(71) Applicant: PURPLE CLOUD DEVELOPMENT PTE. LTD., Singapore (SG)

(72) Inventor: XUE MEI WANG, Hui Zhou City (CN)

(73) Assignee: PURPLE CLOUD DEVELOPMENT PTE. LTD., Singapore (SG)

(21) Appl. No.: 19/043,914

(22) Filed: Feb. 3, 2025

(30) Foreign Application Priority Data
Feb. 1, 2024 (CN) 2024101487827
Jun. 26, 2024 (TW) 113206745

(51) Int. Cl. F28D 15/04

(52) U.S. Cl. CPC F28D 15/046

(57) ABSTRACT

A vapor chamber includes a first plate having a condensing surface, a second plate configured to assemble with the first plate to form a chamber, the condensing surface is facing the second plate, the second plate having a heat absorbing surface facing away from the condensing surface, and the heat absorbing surface is configured to thermally coupled to a heat source, and a condensing assembly being disposed on the condensing surface so that outer surfaces of the condensing assembly and the condensing surface are integrated to form a thermal exchange surface, the thermal exchange surface is configured to condense a vaporized cooling fluid into liquid.

### RELATED APPLICATIONS

This US application claims the benefit of priority to Taiwan application No. 113206745, filed on Jun. 26, 2024, which claims priority to China application No. 202410148782.7, filed on Feb. 1, 2024, of which is incorporated herein by reference in its entirety.

### TECHNICAL FIELD

The present disclosure is related to thermal management of electronic systems in general and more particularly but not limited to vapor chambers.

### BACKGROUND

With the increase of the processing speed and performance of electronic components for electronic devices, such as application-specific integrated circuits (ASICs) and central processing units (CPU) for electronic devices, the amount of heat generated during operation of the electronic devices increases. The generated heat increases the temperature of the electronic devices, including the electronic components thereof, and, if the heat cannot be dissipated effectively, reliability and performance of the electronic devices are reduced.

To prevent overheating of an electronic component of a thin and compact electronic device, a vapor chamber may be used. The generated heat of the electronic component is conducted from a small and limited area of the electronic component to a greater area of the vapor chamber, and the generated heat may be dispersed inefficiently along the vapor chamber. Consequently, the vapor chamber may not adequately cool the electronic component, which could cause it to overheat.

### SUMMARY

Aspects of the disclosure provide a vapor chamber. The vapor chamber includes a first plate having a first plate having a condensing surface, a second plate being configured to assemble with the first plate to form a chamber; at least one condensing structure being disposed on the condensing surface so that outer surfaces of the one condensing structure and the condensing surface are integrated to form a thermal exchange surface, which is configured to condense a vaporized cooling fluid into liquid.

In an embodiment, the second plate can further include a base plate and a first recessed structure being recessed from the base plate in a direction away from the first plate, wherein the condensing structure is disposed in a region of the condensing surface corresponding to the first recessed structure.

In an embodiment, the second plate can further include a second recessed structure being recessed from the base plate in a direction away from the first plate, and the condensing structure is disposed in a region of the condensing surface corresponding to the second recessed structure.

In an embodiment, the second plate can further include a base plate, a first recessed structure being recessed from the base plate in a direction away from the first plate, and a second recessed structure being recessed from the first recessed structure in a direction away from the first plate, and the condensing structure is disposed in a region of the condensing surface corresponding to the second recessed structure.

In an embodiment, the vapor chamber can further include a first wick structure being disposed on the condensing surface.

In an embodiment, the vapor chamber can further include a core wick structure being disposed on a region of the first wick structure corresponding to the second recessed structure.

In an embodiment, the first wick structure can further be disposed on the condensing structure.

In an embodiment, the vapor chamber can further include a second wick structure being disposed between inner surfaces of the first recessed structure and the second recessed structure.

In an embodiment, the vapor chamber can further include at least one first support structure being disposed on the inner surface of the first recessed structure and passes through the second wick structure and the first wick structure to connect the condensing surface.

In an embodiment, the vapor chamber can further include at least one second support structure being disposed on the inner surface of the second recessed structure and passes through the second wick structure and the first wick structure to connect the condensing surface.

In an embodiment, the vapor chamber can further include at least one third wick structure being disposed on a sidewall of the at least one second wick structure, the first wick structure connects to the second wick structure via the at least one third wick structure.

In an embodiment, the first wick structure and the second wick structure are selected made of at least one of a metal mesh, a powder sintered body or a ceramic sintered body. In an embodiment, the third wick is a powder sintered body.

In an embodiment, the vapor chamber can further include at least one heat pipe being disposed on the first plate. In an embodiment, the first plate can include at least one through hole, the heat pipe is disposed in the through hole, the heat pipe having a pipe chamber connected with the chamber via the through hole on the first plate, and the heat pipe passes through the first wick structure to connects with the second wick structure.

In an embodiment, the heat pipe can include a pipe wick structure disposed on an inner surface, the pipe wick structure is partially connected with the second wick structure. In an embodiment, the pipe wick structure is partially connected with the second wick structure via metal bonding.

Aspects of the present disclosure provide a vapor chamber. The vapor chamber includes a first plate having a condensing surface, a second plate, being configured to assemble with the first plate to form a chamber, the condensing surface is facing the second plate, the second plate having a heat absorbing surface facing away from the condensing surface; the heat absorbing surface is configured to thermally coupled to a heat source, and a condensing assembly being disposed on the condensing surface so that outer surfaces of the condensing assembly and the condensing surface are integrated to form a thermal exchange surface configured to condense a vaporized cooling fluid into liquid.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective vapor chamber 100 according to aspects of the present disclosure.

FIG. 2 illustrates an exploded view of the vapor chamber 100 as shown in FIG. 1.

FIG. 3 illustrates another exploded view of the vapor chamber 100 as shown in FIG. 1.

FIG. 4 illustrates an exploded view of a vapor chamber 100A according to aspects of the present disclosure.

FIG. 5 illustrates another exploded view of a vapor chamber 100A as shown in FIG. 4.

FIG. 6 illustrates an exploded view of a vapor chamber 100B according to aspects of the present disclosure.

FIG. 7 illustrates another exploded view of a vapor chamber 100B as shown in FIG. 6.

FIG. 8 illustrates a perspective view vapor chamber 100C according to aspects of the present disclosure.

FIG. 9 illustrates an exploded view of the vapor chamber 100C as shown in FIG. 8.

FIG. 10 illustrates another exploded view of the vapor chamber 100C as shown in FIG. 8.

FIG. 11 illustrates an exploded view of a vapor chamber 100D according to aspects of the present disclosure.

FIG. 12 illustrates another exploded view of a vapor chamber 100D as shown in FIG. 11.

FIG. 13 illustrates an exploded view of a vapor chamber 100E according to aspects of the present disclosure.

FIG. 14 illustrates another exploded view of a vapor chamber 100E as shown in FIG. 13.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

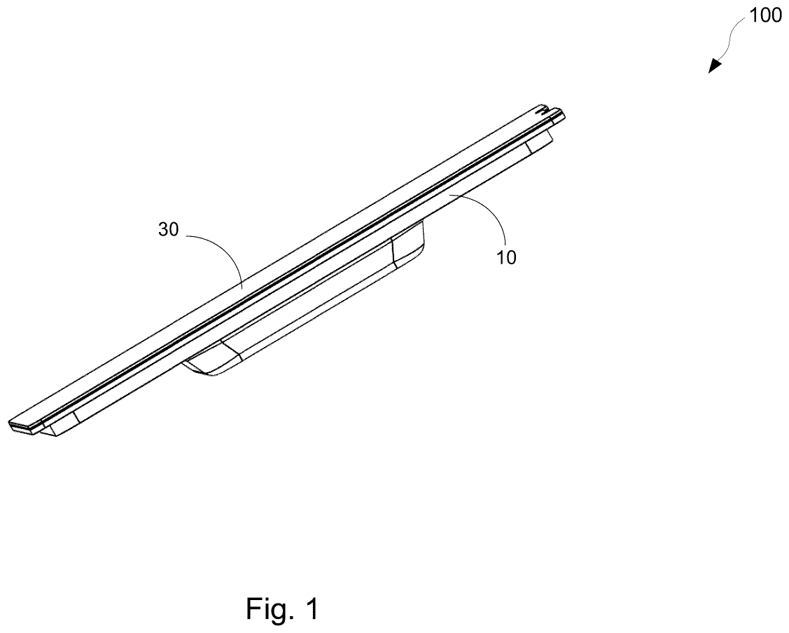

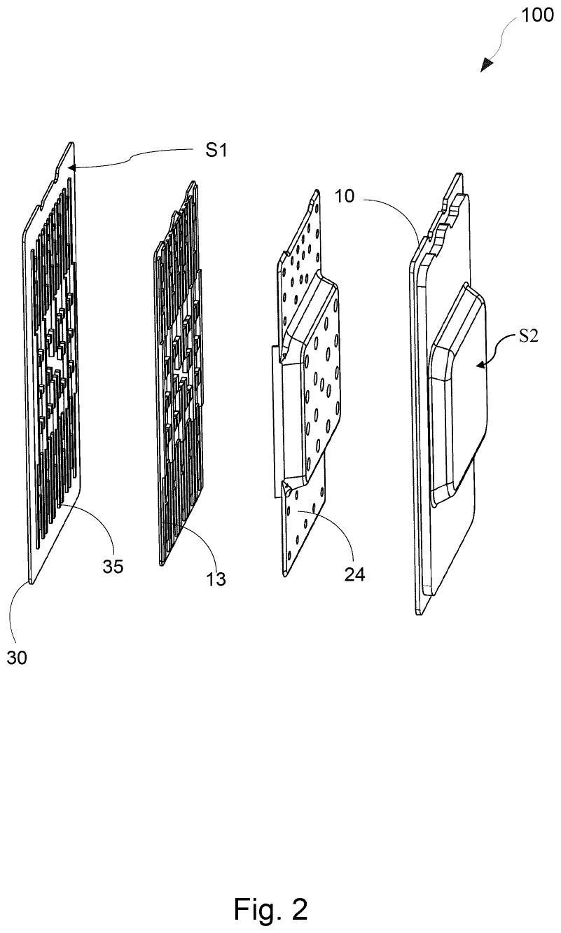

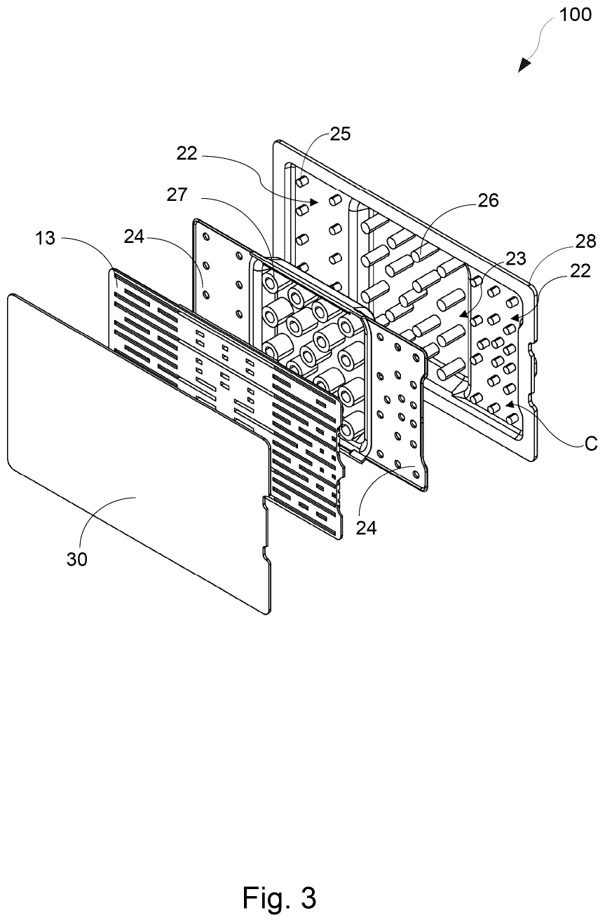

Referring to FIGS. 1-3. FIG. 1 illustrates a perspective view of a vapor chamber 100 according to aspects of the present disclosure. FIGS. 2 and 3 illustrates exploded views of the vapor chamber 100 as shown in FIG. 1. The vapor chamber 100 includes a first plate 10 and a second plate 30 that can be connected together to form a liquid-tight chamber C therein. A first wick structure 24 is disposed on the inner surface of the first plate 10 and a second wick structure 13 is disposed on the inner surface of the second plate 30. The vapor chamber 100 further includes a third wick structure 27. The inner surface of the second plate 30 is also a condensing surface S1 of the second plate 30. The vapor chamber 100 also includes a plurality of condensing structures 35. The first plate 10 includes a base 28, a first recessed structure 22, a second recessed structure 23 and a heat absorbing surface S2 on the outer surface. The heat absorbing surface S2 is thermally coupled to a heat source (not shown). The first recessed structure 22 and the second recessed structure 23 are recessed and extends from the base 28 in a direction away from the second plate 30. The second recessed structure 23 is recessed farther than the first recessed structure 22. Namely, the second recessed structure 23 is recessed from the first recessed structure 22 in the direct away from the second plate 30.

The first plate 10 also includes a plurality of first support structures 25, and a plurality of second support structures 26. The second support structures 26 are coupled to and extend from the second recessed structure 23 in a direction towards the second plate 30. The first support structures 25 are coupled to and extends from the first recessed structure 22 in a direction towards the second plate 30. The second recessed structure 23 is the evaporation region of the vapor chamber 100 as being close to the heat source. Namely, the center region of the liquid-tight chamber C adjacent to the heat source is the evaporation region of the vapor chamber 100. In contrast, the first recessed structure 22 is the condensation region of the vapor chamber 100. Namely, the region surrounding the center region in the liquid-tight chamber C is the condensation region of the vapor chamber 100. The number of the first support structure 25 and the second support structures 26 can be plural but is not required to be. In some embodiments, the number of the first support structure 25 and the second support structure 26 can respectively be single.

The first wick structure 24 can be disposed on the inner surface of the first recessed structure 22 and the second recessed structure 23. The first wick structure 24 includes through holes for the first support structures 25 and the second support structures 26 to pass through. The third wick structures 27 are disposed on the sidewalls of the plurality of second support structures 26. The first wick structure 24 connects to the second wick structure 13 via the third wick structures 27. In some embodiments, the first wick structure 24 and the second wick structure 13 can each respectively include at least one of a sintered metal powder wick, a metal mesh wick, or a sintered ceramic powder wick, or any combinations of the foregoing wicks. In some embodiments, the third wick structure 27 includes a sintered powder wick formed by a sintering process. In some embodiments, the first wick structure 24 and the third wick structure 27 can be formed through a single sintering process. In some embodiments, the first wick structure 24 and the third wick structure 27 can be formed through multiple sintering processes. The number of the third wick structure 27 is determined by and corresponding to the number of the second support structure 26.

The plurality of condensing structures 35 are disposed on the second plate 30. Specifically, the condensing structures 35 are disposed on the condensing surface S1 and spaced apart from each other. The second wick structure 13 is disposed on the plurality of condensing structures 35. The inward facing surfaces of the condensing structures 35 and the condensing surface S1 together can form a thermal exchange surface to increase the thermal exchange area, and in turn, increase the thermal dissipation efficiency of the vapor chamber 100. The liquid cooling fluid can vaporize in the evaporation region, flow towards the condensation region, and condense back to liquid form at the thermal exchange surface to flow back to the evaporation region.

The number of the condensing structure 35 can be changed according to the specific application of the vapor chamber. For example, in an embodiment, the number of the condensing structure 35 can be multiple. In some other embodiments, the number of the condensing structure 35 can be just one. Also, in some embodiments, the disposed location of the condensing structures 35 can correspond to the first recessed structure 22 and the second recessed structure 23. In some other embodiments, the disposed location of the condensing structures 35 can correspond to the first recessed structure 22 only. However, the disposed location of the condensing structures 35 at least needs to be corresponding to the condensation region of the liquid-tight chamber C.

In some embodiments, the height of each of the condensing structures 35 can be different from each other. For example, the height of the condensing structures 35 that are corresponding to the second recessed structure 23 can be greater than the height of the condensing structures 35 that are corresponding to the first recessed structure 22. In some embodiments, the condensing structures 35 can have uniform height. In some embodiments, the length of each of the condensing structures 35 can be different from each other. In some embodiments, the condensing structures 35 can have uniform length.

The second wick structure 13 is disposed on the condensing surface S1 and the inward facing surfaces of the condensing structures 35. That is, the second wick structure 13 is disposed on the thermal exchange surface and forms a condensation assembly with the condensing structures 35.

The first wick structure 24 can be selected from various materials. For example, the first wick structure 24 can be selected from a metal mesh, a powder sintered body, and a ceramic sintered body, or any combinations of the foregoing materials.

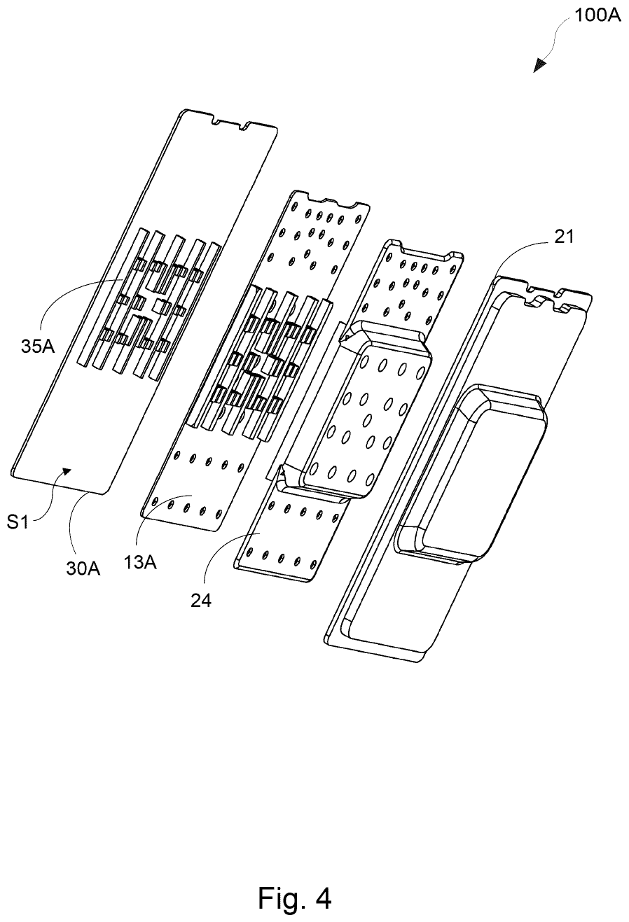

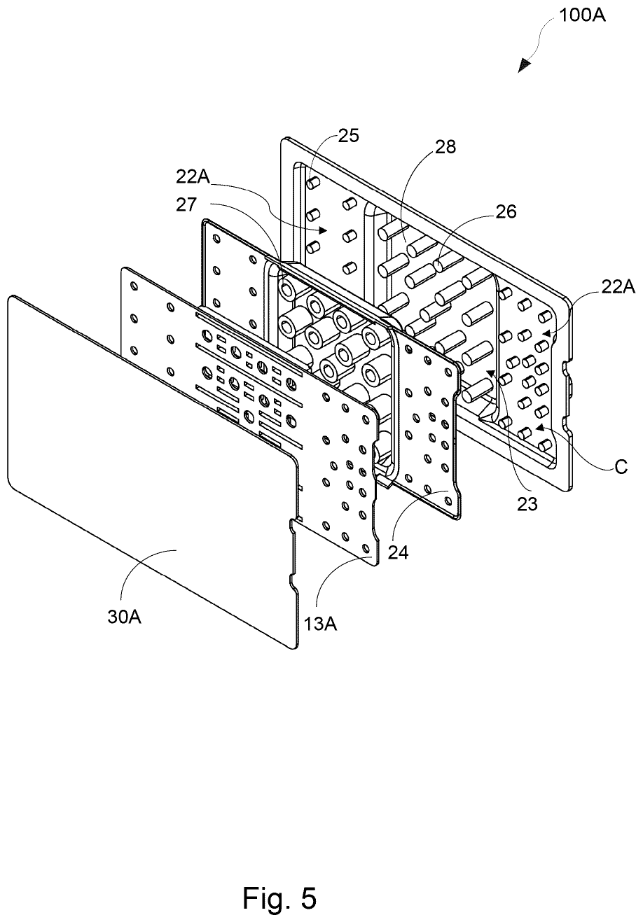

Referring to FIGS. 4-5, which illustrates exploded views of a vapor chamber 100A according to aspects of the present disclosure. The vapor chamber 100A may be similar in some respects to the vapor chamber 100 of FIG. 1, and so the differences will be described in detail below and the similarities will not be repeated. The condensing structures 35A are disposed on the condensing surface S1 of the second plate 30A. Specifically, the disposed location of the condensing structures 35A is only corresponding to the evaporation region of the liquid-tight chamber C. Namely, the disposed location of the condensing structures 35A on the condensing surface S1 is corresponding to the second recessed structure 23 of the first plate 10. The second wick structure 13A includes through holes for the first support structures 25 and the second support structures 26 to go though. In this way, the first support structures 25 and the second support structures 26 are in direct contact with the second plate 30A and the condensing surface S1.

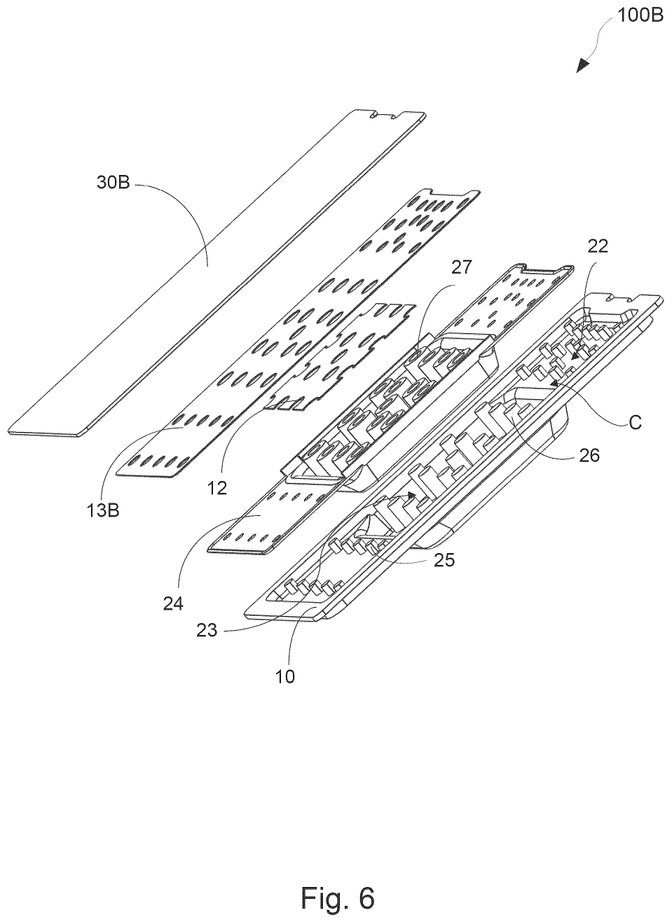

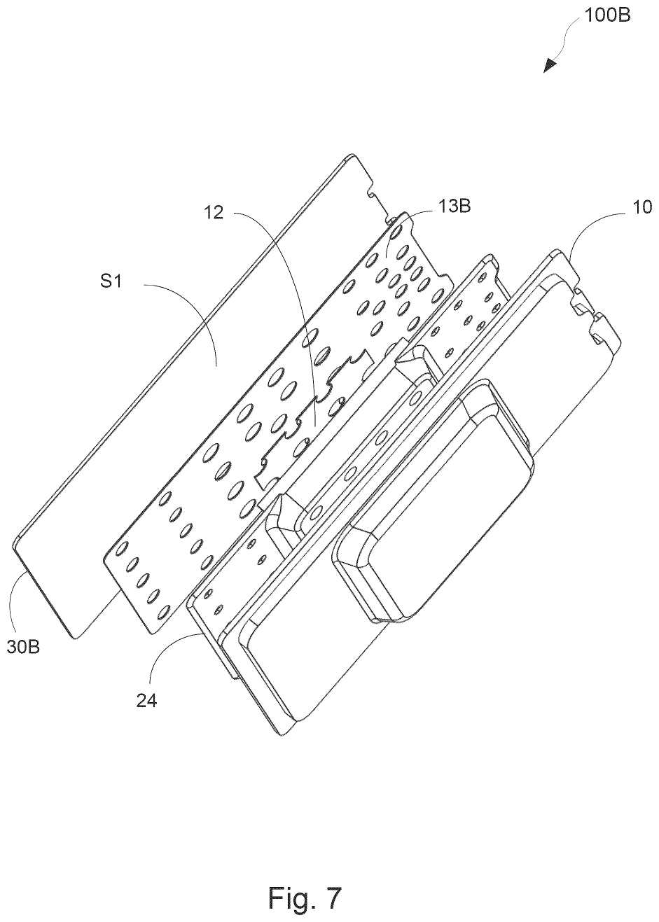

Referring to FIGS. 6-7, which illustrates exploded views of a vapor chamber 100B according to aspects of the present disclosure. The vapor chamber 100B may be similar in some respects to the vapor chamber 100 and 100A of FIG. 1, and so the differences will be described in detail below and the similarities will not be repeated. The vapor chamber 100B does not include the condensing structures compares to vapor chamber 100 and 100A, instead, the vapor chamber 100B includes a core wick structure 12 that is disposed in between the first wick structure 24 and the second wick structure 13B. Specifically, the disposed location of the core wick structure 12 is corresponding to the evaporation region of the liquid-tight chamber C. Namely, the disposed location of the core wick structure 12 is corresponding to the second recessed structure 23 of the first plate 10. The core wick structure 12 includes through holes for the second support structures 26 to pass through and in direct contact with the second plate 30B and the condensing surface S1. The core wick structure 12 and the first wick structure 24 together form a condensation assembly. The core wick structure 12 in also in contact with the third wick structure 27. The core wick structure 12 can be selected from various materials. For example, the core wick structure 12 can be selected from a metal mesh, a powder sintered body, and a ceramic sintered body, or any combinations of the foregoing materials. In some embodiments, the vapor chamber 100B can also include the condensing structures being disposed on the condensing surface S1.

Since the core wick structure 12 is disposed in the main thermal dissipation area the condensing surface S1 is corresponding to, the return efficiency of the cooling fluid is increased. In turn, the cooling fluid can flow back to the evaporation region faster, and the thermal dissipation efficiency of the vapor chamber can be enhanced.

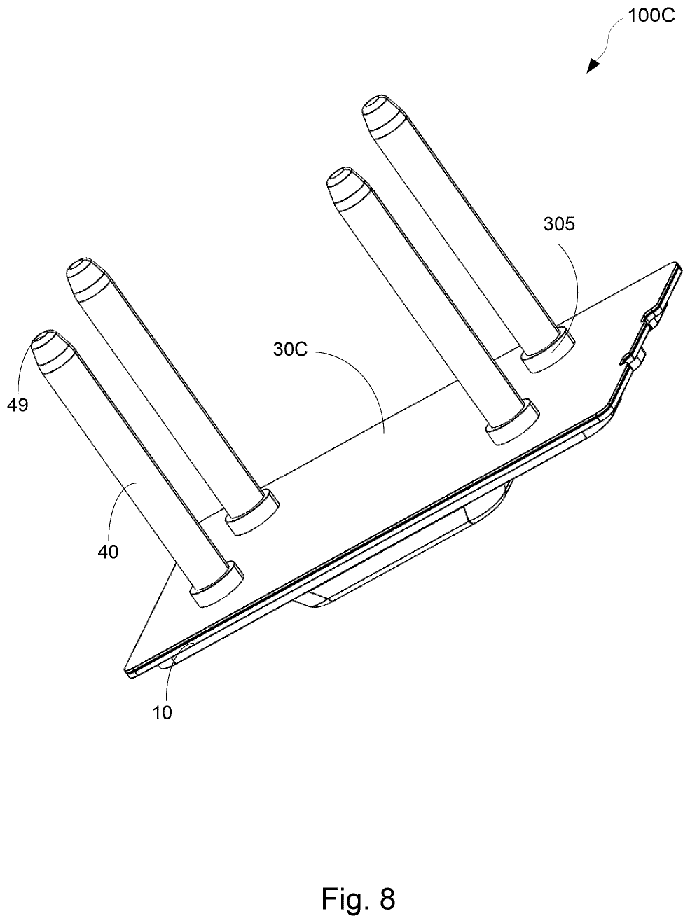

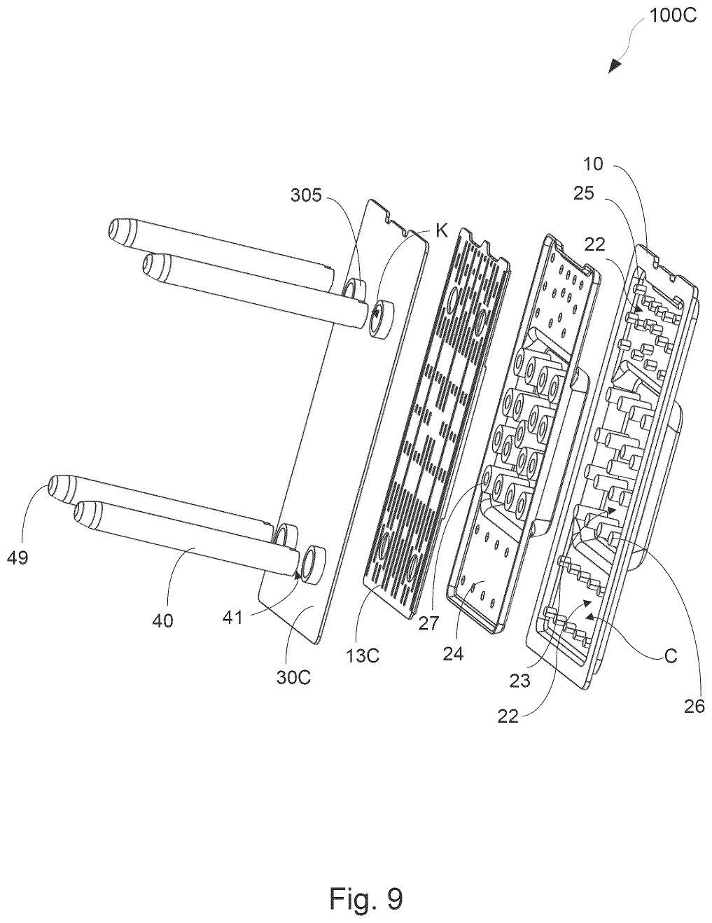

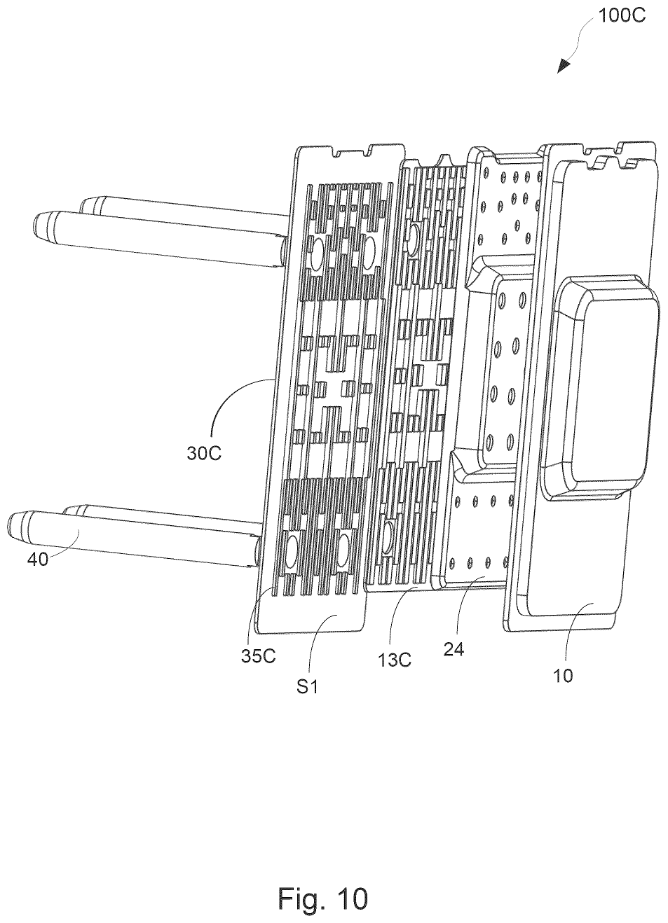

Referring to FIGS. 8-10. FIG. 8 illustrates a perspective view of a vapor chamber 100C according to aspects of the present disclosure. FIGS. 9-10 illustrate exploded views of the vapor chamber 100C as shown in FIG. 8. The vapor chamber 100C may be similar in some respects to the vapor chambers 100 as shown in FIG. 1, and so the differences will be described in detail below and the similarities will not be repeated. The vapor chamber 100C further includes multiple heat pipes 40 respectively includes an inner chamber (not shown), a closed end 49, an open end 41, and a pipe wick structure (not shown). The open end 41 is opposite to the closed end 49 and the inner chamber is connected to the liquid-tight chamber C. The pipe wick structure is disposed on the inner surface of the inner chamber. The second plate 30C includes a plurality of through holes K. Each through hole K respectively includes a flange 305 and the flange 305 respectively extends away from the condensing surface S1. Each heat pipe 40 is inserted into the respective through hole K via the respective flange 305. In some embodiments, the pipe wick structure is coupled to the first wick structure 24 via metal bonding. In some embodiments, the flange 305 may not be required and the heat pipe 40 can directly connect to the outer surface of the second plate 30C without the flange 305.

Similar to the vapor chamber 100, the vapor chamber 100C also includes the condensing structure 35C disposed on the condensing surface S1 of the second plate 30C. The inward facing surfaces of the condensing structures 35 and the condensing surface S1 together can form a thermal exchange surface to increase the thermal exchange area, and in turn, enhance the thermal dissipation efficiency of the vapor chamber 100C. The disposed location of the second wick structure 13C is corresponding to the condensing surface S1 and the inward facing surfaces of the condensing structures 35. That is, the second wick structure 13C is corresponding to the thermal exchange surface and forms a condensation assembly with the condensing structures 35. Further, the second wick structure 13C includes through holes that are corresponding to the through holes K on the second plate 30C in for the cooling fluid to flow to the heat pipes 40.

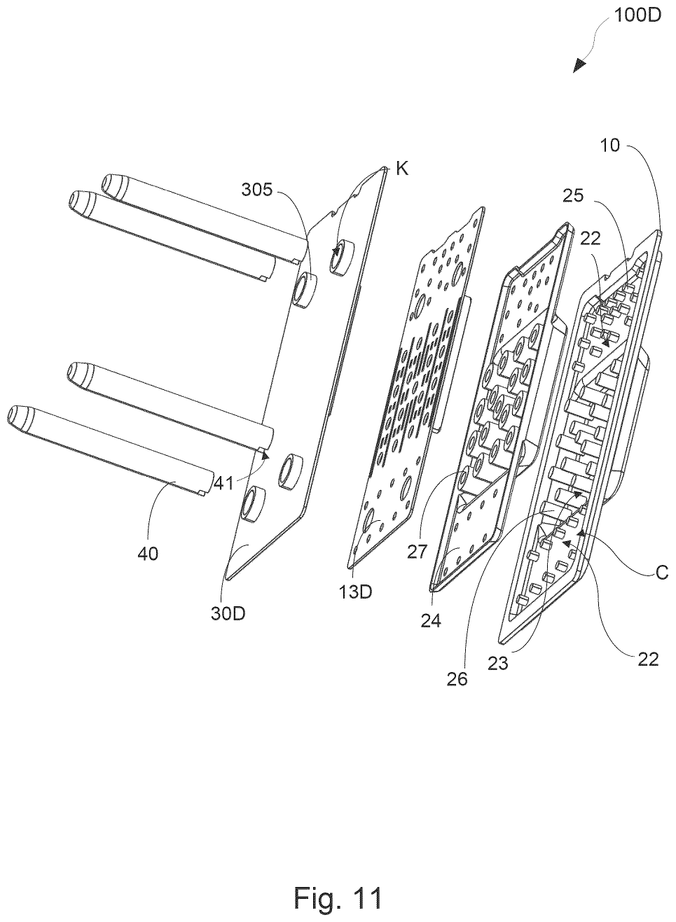

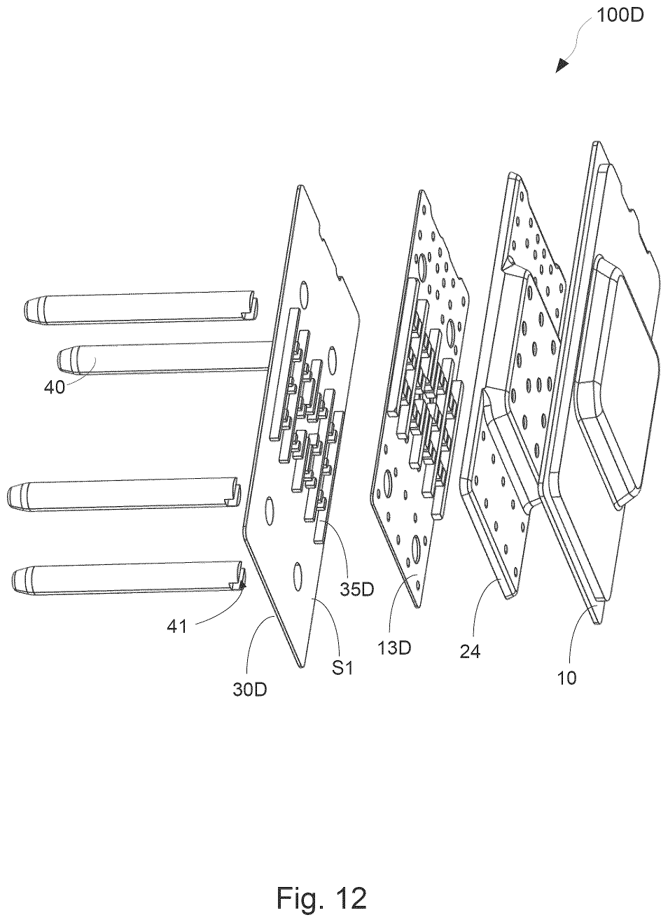

Referring to FIGS. 11-12, which illustrate exploded views of a vapor chamber 100D according to aspects of the present disclosure. The vapor chamber 100D may be similar in some respects to the vapor chambers 100A and 100C of FIGS. 4-5 and 8-10, and so the differences will be described in detail below and the similarities will not be repeated. Similar to the vapor chamber 100C, the vapor chamber 100D include multiple heat pipes 40 respectively includes an inner chamber (not shown), a closed end 49, an open end 41, and a pipe wick structure (not shown). The open end 41 is opposite to the closed end 49 and the inner chamber is connected to the liquid-tight chamber C. The pipe wick structure is disposed on the inner surface of the inner chamber. The second plate 30D includes a plurality of through holes K. Each through hole K respectively includes a flange 305 and the flange 305 respectively extends away from the condensing surface S1. Each heat pipe 40 is inserted into the respective through hole K via the respective flange 305. In some embodiments, the pipe wick structure is coupled to the first wick structure 24 via metal bonding. In some embodiments, the flange 305 may not be required and the heat pipe 40 can directly connect to the outer surface of the second plate 30D without the flange 305.

Similar to the vapor chamber 100A, the vapor chamber 100D includes multiple condensing structures 35D that are disposed on the condensing surface S1 of the second plate 30D. Specifically, the deposed location of the condensing structures 35D is corresponding to the evaporation region of the liquid-tight chamber C. That is, the condensing structures 35D disposed on the condensing surface S1 is corresponding to the second recessed structure 23 of the first plate 10. The second wick structure 13D includes through holes for the first support structures 25 and the second support structures 26 to go though. In this way, the first support structures 25 and the second support structures 26 are in direct contact with the second plate 30D and the condensing surface S1.

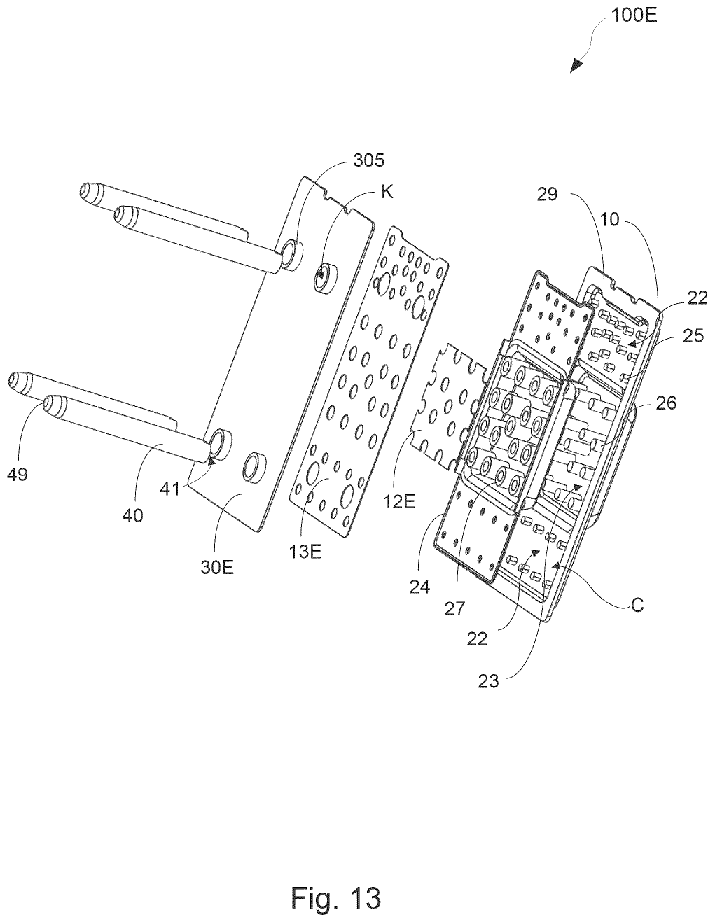

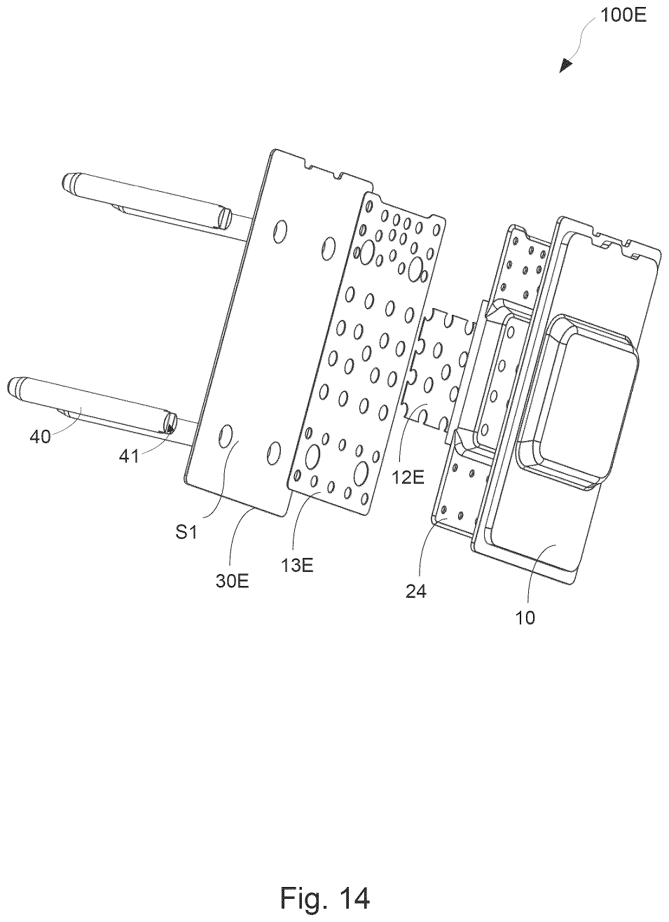

Referring to FIGS. 13-14, which illustrate exploded views of a vapor chamber 100E according to aspects of the present disclosure. The vapor chamber 100E may be similar in some respects to the vapor chambers 100B and 100C of FIGS. 6-7 and 8-10, and so the differences will be described in detail below and the similarities will not be repeated. Similar to the vapor chamber 100C, the vapor chamber 100E include multiple heat pipes 40 respectively includes an inner chamber (not shown), a closed end 49, an open end 41, and a pipe wick structure (not shown). The open end 41 is opposite to the closed end 49 and the inner chamber is connected to the liquid-tight chamber C. The pipe wick structure is disposed on the inner surface of the inner chamber. The second plate 30E includes a plurality of through holes K. Each through hole K respectively includes a flange 305 and the flange 305 respectively extends away from the condensing surface S1. Each heat pipe 40 is inserted into the respective through hole K via the respective flange 305. In some embodiments, the pipe wick structure is coupled to the first wick structure 24 via metal bonding. In some embodiments, the flange 305 may not be required and the heat pipe 40 can directly connect to the outer surface of the second plate 30E without the flange 305.

Similar to the vapor chamber 100B, the vapor chamber 100E does not include the condensing structures, instead, the vapor chamber 100E includes a core wick structure 12E that is disposed in between the first wick structure 24 and the second wick structure 13E. Specifically, the core wick structure 12E is disposed in the evaporation region of the liquid-tight chamber C. Namely, the disposed location of the core wick structure 12 is corresponding to the second recessed structure 23 of the first plate 10. The core wick structure 12E includes through holes for the second support structures 26 to pass through and in direct contact with the second plate 30E and the condensing surface S1. The core wick structure 12E and the first wick structure 24 together form a condensation assembly. The core wick structure 12E is also in contact with the third wick structure 27. The core wick structure 12E can be selected from various materials. For example, the core wick structure 12E can be selected from a metal mesh, a powder sintered body, and a ceramic sintered body, or any combinations of the foregoing materials. In some embodiments, the vapor chamber 100E can also include the condensing structures being disposed on the condensing surface S1.

The abovementioned vapor chambers can include the three-dimensional condensing structures disposed on the condensing surface of the second plate to increase the surface area of the thermal exchange surface integrated between the inward facing surfaces of the condensing structures and the condensing surface for enhancing the thermal dissipation efficiency. The abovementioned vapor chambers can also include the core wick structure being disposed between the first wick structure and the second wick structure and corresponding to the center of the evaporation region to enhance the cooling fluid return efficiency. Therefore, the invention described herein improves the overall thermal dissipation efficiency of the vapor chamber.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean than one of the elements that it introduces.

What is claimed is:

1. A vapor chamber, comprising:
a first plate having a condensing surface;
a second plate, being configured to assemble with the first plate to form a chamber, the condensing surface is facing the second plate, the second plate having a heat absorbing surface facing away from the condensing surface, and the heat absorbing surface is configured to thermally coupled to a heat source; and
a condensing assembly being disposed on the condensing surface so that outer surfaces of the condensing assembly and the condensing surface are integrated to form a thermal exchange surface, the thermal exchange surface is configured to condense a vaporized cooling fluid into liquid.

2. The vapor chamber of claim 1, wherein the second plate includes a base plate, a first recessed structure, and a second recessed structure, the first recessed structure being recessed from the base plate in a direction away from the first plate, and the second recessed structure being recessed from the first recessed structure in the direction away from the first plate.

3. The vapor chamber of claim 2, further comprises a first wick structure and a core wick structure, the first wick structure being disposed on the thermal exchange surface, the core wick structure being disposed on the first wick structure and corresponds to the second recessed structure.

4. The vapor chamber of claim 3, further comprises a second wick structure being disposed in the chamber and on surfaces of the first recessed structure and the second recessed structure.

5. The vapor chamber of claim 4, further comprises at least one first support structure disposed in the first recessed structure, the first support structure passes through the second wick structure and in contact with the first wick structure.

6. The vapor chamber of claim 4, further comprises at least one first support structure disposed in the first recessed structure, the first support structure passes through the second wick structure and the first wick structure, and in contact with the thermal exchange surface.

7. The vapor chamber of claim 5, further comprises at least one second support structure being disposed in the second recessed structure, the second support structure passes through the second wick structure and in contact with the first wick structure.

8. The vapor chamber of claim 6, further comprises at least one second support structure disposed in the second recessed structure, the second support structure passes through the second wick structure and the first wick structure, and in contact with the thermal exchange surface.

9. The vapor chamber of claim 7, further comprises at least one third wick structure disposed on a sidewall of the second support structure, and the first wick structure connects with the second wick structure via the third wick structure.

10. The vapor chamber of claim 8, further comprises at least one third wick structure disposed on a sidewall of the second support structure, and the first wick structure connects with the second wick structure via the third wick structure.

11. The vapor chamber of claim 4, further comprises at least one heat pipe being disposed on the first plate, the heat pipe having a pipe chamber that is connect with the chamber via at least one through hole on the first plate, and the heat pipe passes through the first wick structure to connects with the second wick structure.

12. A vapor chamber, comprising:
a first plate having a condensing surface;
a second plate being configured to assemble with the first plate to form a chamber; and
at least one condensing structure being disposed on the condensing surface so that outer surfaces of the condensing structure and the condensing surface are integrated to form a thermal exchange surface, the thermal exchange surface is configured to condense a vaporized cooling fluid into liquid.

13. The vapor chamber of claim 12, wherein the second plate further comprises:
a base plate; and
a first recessed structure being recessed from the base plate in a direction away from the first plate, wherein the condensing structure disposed in a region of the condensing surface corresponds to the first recessed structure.

14. The vapor chamber of claim 13, wherein the second plate further comprises a second recessed structure being recessed from the first recessed structure in the direction away from the first plate, and the condensing structure disposed in a region of the condensing surface corresponds to the second recessed structure.

15. The vapor chamber of claim 12, wherein the second plate further comprises:
a base plate;
a first recessed structure being recessed from the base plate in a direction away from the first plate; and
a second recessed structure being recessed from the first recessed structure in a direction away from the first plate, and the condensing structure disposed in a region of the condensing surface corresponds to the second recessed structure.

16. The vapor chamber of claim 14 or 15, further comprises a first wick structure being disposed on the condensing surface.

17. The vapor chamber of claim 16, further comprises a core wick structure being disposed on a region of the first wick structure corresponding to the second recessed structure.

18. the vapor chamber of claim 16, wherein the first wick structure is further disposed on the condensing structure.

19. The vapor chamber of claim 17, further comprises a second wick structure being disposed on inner surfaces of the first recessed structure and the second recessed structure.

20. The vapor chamber of claim 19, further comprises at least one first support structure being disposed on the inner surface of the first recessed structure and passes through the second wick structure and the first wick structure to connect the condensing surface.

21. The vapor chamber of claim 20, further comprises at least one second support structure being disposed on the inner surface of the second recessed structure and passes through the second wick structure and the first wick structure to connect the condensing surface.

22. The vapor chamber of claim 21, further comprises at least one third wick structure disposed on a sidewall of the at least one second wick structure, and the first wick structure connects to the second wick structure via the third wick structure.

23. The vapor chamber of claim 19, wherein the first wick structure and the second wick structure are made of at least one of a metal mesh, a powder sintered body, or a ceramic sintered body.

24. The vapor chamber of claim 22, wherein the third wick is a powder sintered body.

25. The vapor chamber of the claim 19, further comprises at least one heat pipe disposed on the first plate.

26. The vapor chamber of claim 25, wherein the first plate includes at least one through hole, the at least one heat pipe is disposed in the at least one through hole, the at least one heat pipe having a pipe chamber that is connected with the chamber via at least one through hole on the first plate, and the one heat pipe passes through the first wick structure to connects with the second wick structure.

27. The vapor chamber of claim 25, wherein the at least one heat pipe includes a pipe wick structure disposed on an inner surface, the pipe wick structure is partially connected with the second wick structure.

28. The vapor chamber of claim 27, wherein the pipe wick structure is partially connected with the second wick structure via metal bonding.
